(19) United States
(12) Patent Application Publication
(10) Pub. No.: US 2007/0161261 A1
(43) Pub. Date: Jul. 12, 2007

(54) Methods for fabricating carbon nano-tube powders and field emission display devices

(75) Inventors: Lih-Hsiung Chan, Kaohsiung City (TW); Yau-Chen Jiang, Hsinchu County (TW); Liang-You Jiang, Taipei County (TW); Yu-Yang Chang, Tainan (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/491,720

(22) Filed: Jul. 24, 2006

(30) Foreign Application Priority Data
Jan. 11, 2006 (TW) TW95101018

(51) Int. Cl. H01L 21/00

(52) U.S. Cl. 438/800

(57) ABSTRACT

Methods for fabricating carbon nano-tube (CNT) powders and field emission display devices. Carbon nano-tube powders are deposited and gathered in a vacuum chamber. A physical surface treatment is performed on the carbon nano-tube powders. The carbon nano-tube powders are mixed into a paste and screen printed on a substrate, wherein the physical surface treatment comprises laser radiation, ion-beam bombardment, high energy particle bombardment, or electron-beam bombardment.

### BACKGROUND OF THE INVENTION

1. Field of the Invention

The invention relates to methods for fabricating field emission display (FED) devices, and in particular to methods for fabricating for large scale thick-film carbon nano-tube field emission display (CNT-FED) devices.

2. Description of the Related Art

Field emission display (FED) devices are panelized conventional cathode ray tube (CRT) displays. By using screen printing technology, large scale FED devices can be achieved. Conventional larger scale FED devices have many advantages such as low volume, light weight, low power consumption, excellent image quality, and are applicable to a variety of electronic and communication devices. Carbon nano-tube or other nano-scale field emitters have benefits such as low threshold field, high emission current density, and high stability due to lower threshold voltage, higher light efficiency, higher viewing angle, and lower power consumption.

Compared with conventional large scale display devices, CRT displays have excellent display quality but a large amount of occupy space. Projection TVs occupy less space but offer poor display quality. Plasma display panel (PDP) displays exhibit lighter, thinner features and can be fabricated by screen printing, nonetheless, they require high power consumption.

Accordingly, self-emission display devices with low threshold voltage, high luminance efficiency, high brightness, and simplified driving procedures are required. Moreover, thick film screen printing CNT-FED devices are adapted due to their large scale productivity and low cost.

Conventional CNT-FED devices are fabricated by thick-film screen printing to achieve large scale production. Carbon nano-tube powders are fabricated by arc discharging, chemical vapor deposition (CVD), or laser ablation. Arc discharging can provide CNT powders with excellent microstructure, physical and electrical properties, but lower production and a large amount of microcarbon particle byproducts. On the other hand, CVD can provide higher production but inferior microstructure, physical and electrical properties. Microcarbon particle byproducts, however, are unavoidable in both arc discharging and chemical vapor deposition, thus, an additional treatment including thermal or chemical solvent treatments on carbon nano-tube powders is required.

U.S. Pat. No. 6,890,230, the entirety of which is hereby incorporated by reference, discloses a fabrication method of a field emission display device performing laser activation to create uniformed orientation of carbon nano-tubes. FIG. 1 is a cross section of a conventional method of laser activation to create carbon nano-tube (CNT) emitters with uniform orientations. In FIG. 1, a field emission display device comprises a lower substrate 10 with a cathode 20 thereon. A CNT thick film 30 is formed on the cathode 20 as a field emitter. An upper substrate 60 is disposed opposing the lower substrate 20. An anode 50 is disposed on the upper substrate 60. A voltage controller 40 applies bias between the upper substrate 60 and the lower substrate 20, thereby controlling the field emission display device. The conventional method provides a laser source 70 passing through the upper substrate 60 and anode 50 and radiating the CNT thick film 30 to activate the field emitter. FIG. 2 is a cross section of the activated field emission display device by laser treatment of FIG. 1.

The activated field emission display device by a laser treatment, however, can be damaged due to undesirable heating. For example, the upper substrate 60, anode 50, dielectric layer and gate may be damaged by laser heating. Moreover, if the laser treatment is performed after the field emission display device is assembled, it is difficult to address and align the laser source, inter alias, for high definition FED device, resulting in intricate fabrication procedures and reduced throughput.

### BRIEF SUMMARY OF THE INVENTION

A detailed description is given in the following embodiments with reference to the accompanying drawings.

Accordingly, a laser treatment method for CNT powders is provided to disentangle aggregation of the carbon nano-tube (CNT) powders and improve uniformity of the carbon nano-tube field emission display device.

According to an embodiment of the invention, a method for fabricating carbon nano-tube powders comprises: synthesizing carbon nano-tube powders by vacuum deposition in a vacuum chamber; performing physical treatment on the carbon nano-tube powders; and mixing the carbon nano-tube powders into a paste.

According to another embodiment of the invention, a method for fabricating a carbon nano-tube field emission display comprises: synthesizing carbon nano-tube powders by vacuum deposition in a vacuum chamber; performing physical treatment on the carbon nano-tube powders; mixing the carbon nano-tube powders into a paste; applying the paste on a first substrate by screen printing; and assembling a second substrate opposing the first substrate with a wall structure interposed therebetween.

### BRIEF DESCRIPTION OF THE DRAWINGS

The file of this patent contains at least one drawing executed in color. Copies of this patent with color drawing(s) will be provided by the Office upon request and payment of the necessary fee.

The present invention can be more fully understood by reading the subsequent detailed description and examples with references made to the accompanying drawings, wherein:

FIG. 1 is a cross section of a convention method of laser activation to create carbon nano-tube (CNT) emitters with uniform orientations;

FIG. 2 is a cross section of the activated field emission display device by laser treatment of FIG. 1;

FIG. 3 is a flowchart illustrating fabrication steps of a carbon nano-tube field emission display device according to an embodiment of the invention;

FIG. 4 is a cross section of a CNT-FED device according to an exemplary embodiment of the invention;

FIGS. 5A and 5B show a side-by-side comparison of scanning electron microscopic (SEM) images of CNT powders before and after laser treatment;

FIGS. 6A and 6B show a side-by-side comparison of display brightness of the CNT-FED devices after laser treatments;

FIG. 7 shows Raman spectra comparing the CNT powders before and after laser treatments; and

FIG. 8 shows emission current dependent from applied field of the CNT powders before and after laser treatments.

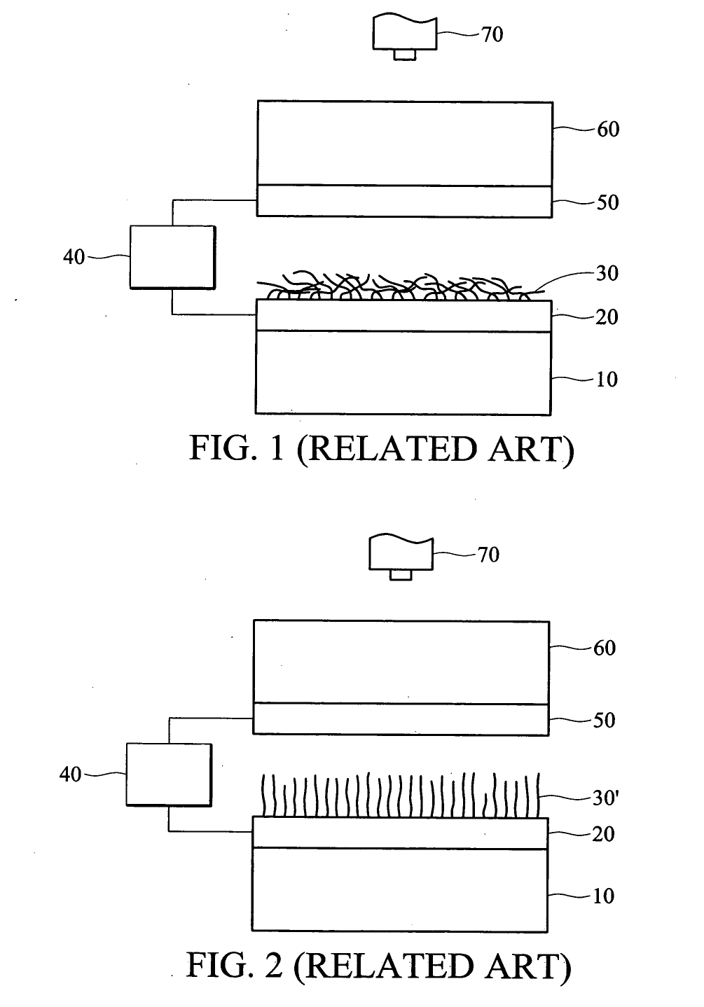

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention is directed to a laser treatment method for carbon nano-tube (CNT) powders effectively disentangling aggregation of the carbon nano-tube (CNT) powders and improving uniformity of the carbon nano-tube field emission display device.

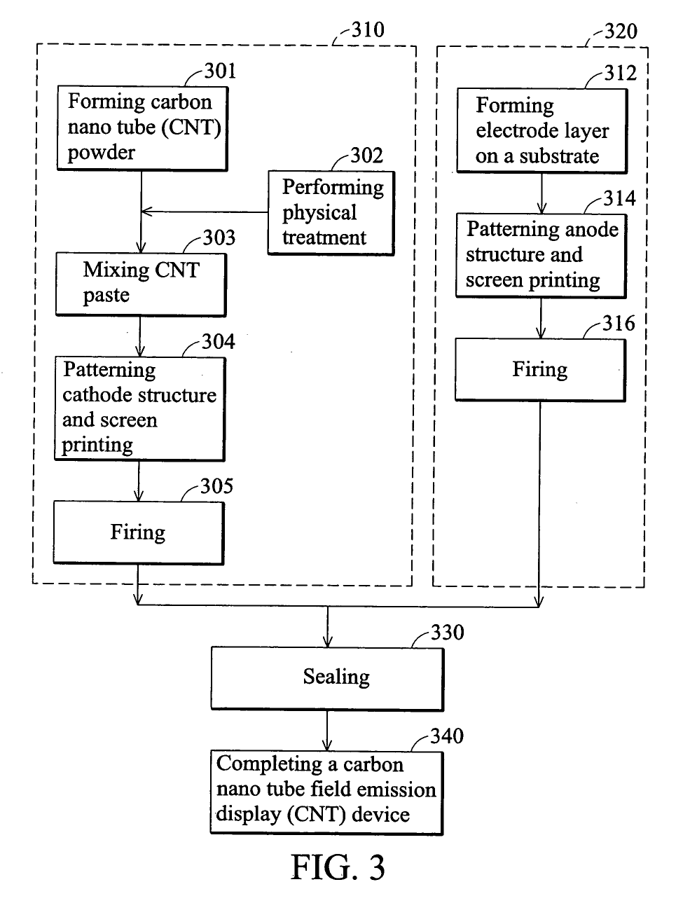

FIG. 3 is a flowchart illustrating fabrication steps of a carbon nano-tube field emission display device according to an embodiment of the invention. In step 310, a lower substrate of the CNT-FED device is formed. In step 320, an upper substrate of the CNT-FED device is formed. In step 330, the lower substrate and the upper substrate are assembled and sealed in a vacuum, thus the carbon nano-tube field emission display (CNT) device is complete.

Step 310 of forming a lower substrate of the CNT-FED device comprises synthesizing carbon nano-tube powders (step 301). For example, CNT powders are fabricated by arc discharging, chemical vapor deposition (CVD), or laser ablation. The CNT powders are gathered in a container. In step 302, the CNT powders are positioned under a laser treatment apparatus, preferably a matrix controllable scanning laser treatment apparatus. According to an embodiment of the invention, the CNT powders are preferably irradiated by 30 KW ArKr scanning laser apparatus. The aggregation of the carbon nano-tube (CNT) powders is disentangled after laser treatment. Although the CNT powders are radiated by laser treatment, other physical treatments such as ion-bean, high energy particle, or electron-beam bombardment are also applicable.

After the laser treatment, the CNT powders are mixed into a CNT paste in step 303. Next, in step 304, a patterned cathode structure is formed by screen printing the CNT paste on a substrate and sintering (step 305) to complete the lower substrate of the carbon nano-tube field emission display (CNT-FED) device.

Step 320 of forming an upper substrate of the CNT-FED device comprises forming a conductive layer or electrode on a substrate (step 312). Next, in step 314, a patterned anode structure is formed on the substrate and sintered (step 305). A fluorescent layer is formed on the anode structure to complete the upper substrate of the carbon nano-tube field emission display (CNT-FED) device.

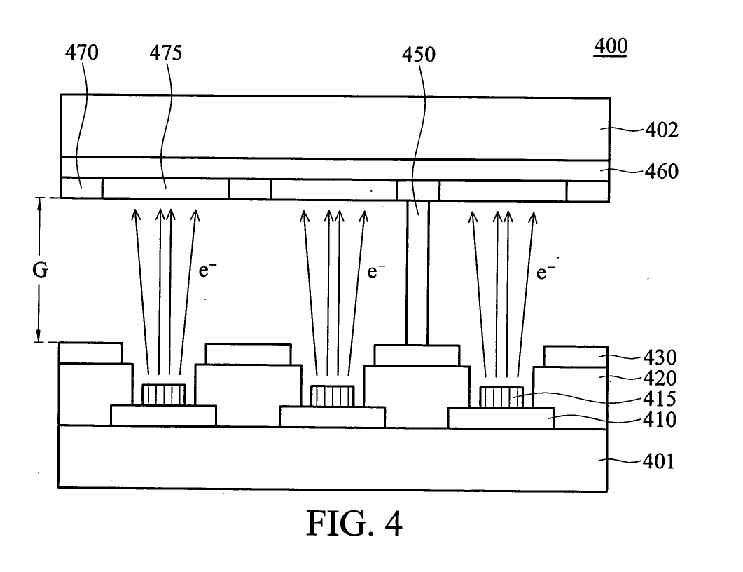

FIG. 4 is a cross section of a CNT-FED device according to an exemplary embodiment of the invention. In FIG. 4, a CNT-FED device comprises a lower substrate 401 and an upper substrate 402. A wall structure 450 or a rib structure with separates the lower and upper substrates with a predetermined gap G. The lower and upper substrates are sealed in vacuum. The lower substrate 402 includes a patterned cathode structure 410. A CNT thick film 415 is disposed on the patterned cathode structure 410 to serve as a field emitter. A dielectric layer 420 surrounding the patterned cathode structure 410 is disposed on the lower substrate 402. A gate electrode 430 is disposed on the dielectric layer 420.

An anode electrode 460 is disposed on the upper substrate 402. Red, green, and blue fluorescent layers 475 are alternatively disposed on the anode electrode 460. A black matrix 470 is disposed between the red, green, and blue fluorescent layers 475.

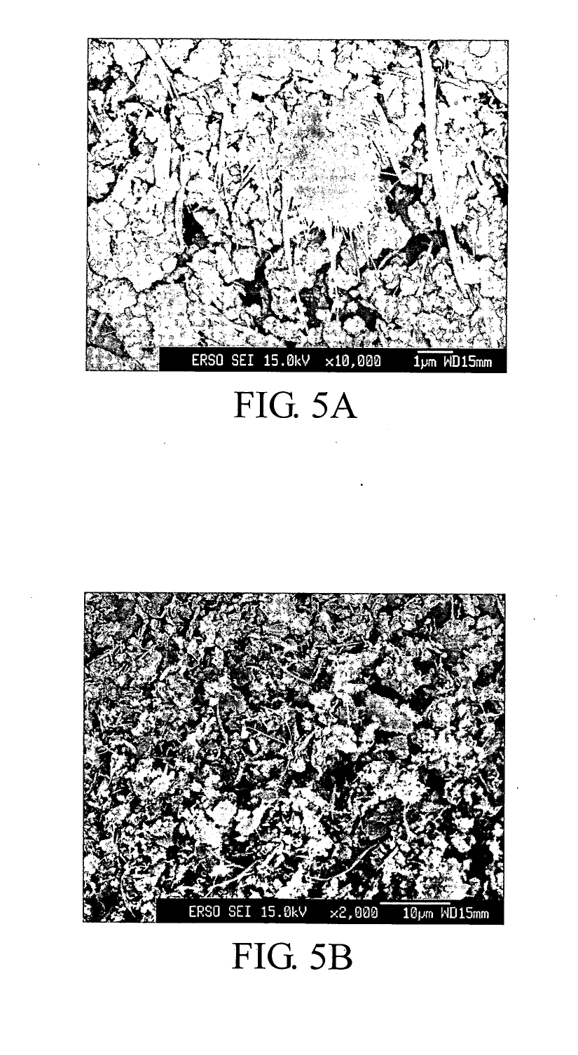

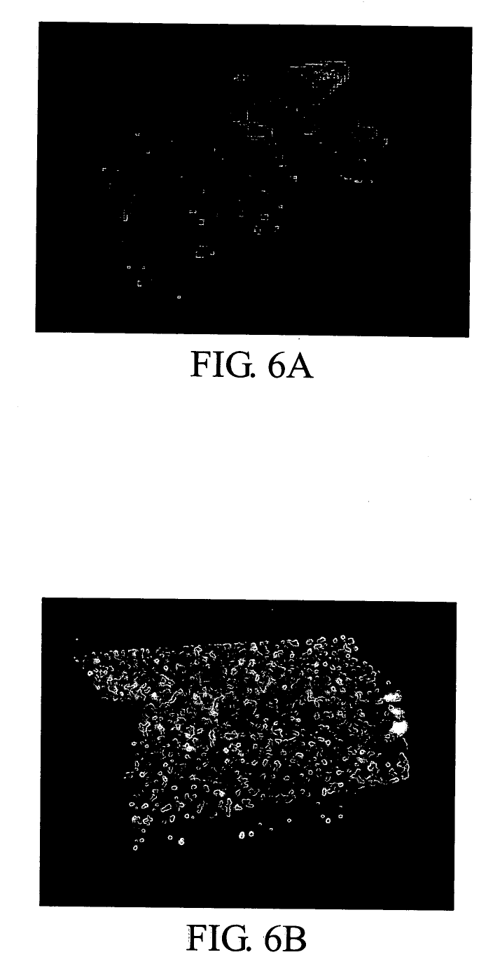

Since the CNT powders treated by laser radiation are burned to disentangle aggregation of the CNT powders, exposing more carbon nano-tubes, thus improving uniformity of the carbon nano-tube field emission display device. FIGS. 5A and 5B show a side-by-side comparison of scanning electron microscopic (SEM) images of CNT powders before and after laser treatment. Referring to FIG. 5B, since more carbon nano-tubes are disentangled and exposed, more emitters are provided, thus improving brightness and uniformity of the CNT-FED device. The brightness of the CNT-FED device after laser treatment is illustrated in FIG. 6B. Conversely, referring to FIG. 5A, the untreated carbon nano-tubes are mixed up with aggregation and carbon powders. If the carbon nano-tubes are encapsulated by aggregation and carbon powders, electrons are difficult ejected from the emitters, thus reducing brightness and uniformity of the CNT-FED device. The display brightness of the CNT-FED device before laser treatment is illustrated in FIG. 6A.

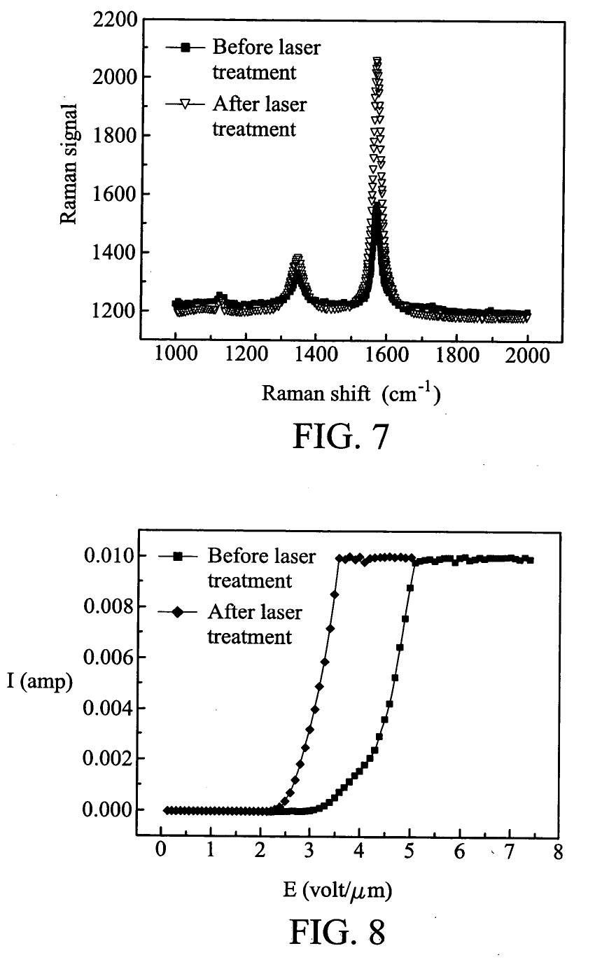

FIG. 7 shows Raman spectrums comparing the CNT powders before and after laser treatments. The CNT powders before and after laser treatments are separately measured by Raman spectrum analyzers. Referring to FIG. 7, the intensity ratio of the graphite structure I_{G} and the diamond structure I_{D}, i.e., I_{G}/I_{D} of each Raman spectrum shows the CNT powders after laser treatment include a higher graphite structure. FIG. 8 shows emitted current dependent on the applied field of the CNT powders before and after laser treatments. Since the CNT powders after laser treatment has a higher degree of graphitization, better field emission properties such as lower threshold voltage and higher saturation current can be achieved.

Referring to FIG. 8, the threshold voltage of the CNT powders is reduced from Vₜᵤᵣₙ₋ₒₙ=3.2V/μm to 2.2V/μm after laser treatment, and the voltage required to reach 10 mA saturation current is reduced from 4.75 V/μm to 3.3V/μm.

Note that the method of laser treatment of the CNT powders for use in the invention is not limited to the CNT-FED device described above, and may be another CNT application such as electrophoresis deposited CNT, nano composite powders, nano hydrogen storage material powders, or dispersion and extraction of nano carbon powders if applicable.

The invention is advantageous in that a laser treatment method for CNT powders is provided. The CNT powders after laser treatment are mixed into paste and screen printed on a cathode substrate to serve as an electron emitter. The CNT-FED device formed by the cathode substrate comprises high brightness and better uniformity.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements. What is claimed is:

1. A method for fabricating carbon nano-tube powders, comprising:
synthesizing carbon nano-tube powders by vacuum deposition in a vacuum chamber; and
performing physical treatment on the carbon nano-tube powders.

2. The method as claimed in claim 1, wherein the vacuum deposition comprises arc discharge, chemical vapor deposition (CVD), and laser ablation.

3. The method as claimed in claim 1, wherein the step of performing physical treatment comprises laser irradiation, and an ion-beam bombardment, a high energy particle bombardment, or an electron-beam bombardment.

4. The method as claimed in claim 3, wherein the step of laser irradiation comprises irradiating the carbon nano-tube powders with 30 kW ArKr laser.

5. The method as claimed in claim 3, wherein the carbon nano-tube powders comprise exposed carbon nano-tubes after laser irradiation.

6. The substrate structure as claimed in claim 3, wherein the carbon nano-tube powders comprise graphitized bonding in the carbon nano-tubes after laser irradiation.

7. The method as claimed in claim 1, further comprising:
mixing the carbon nano-tube powders into a paste; and
applying the paste on a substrate by screen printing.

8. A method for fabricating a carbon nano-tube field emission display, comprising:
synthesizing carbon nano-tube powders by vacuum deposition in a vacuum chamber;
performing physical treatment on the carbon nano-tube powders;
mixing the carbon nano-tube powders into a paste;
applying the paste on a first substrate by screen printing; and
assembling a second substrate opposing the first substrate with a wall structure interposed therebetween.

9. The method as claimed in claim 8, wherein the vacuum deposition comprises arc discharging, chemical vapor deposition (CVD), and laser ablation.

10. The method as claimed in claim 8, wherein the step of performing physical treatment comprises a laser irradiation, an ion-beam bombardment, a high energy particle bombardment, or an electron-beam bombardment.

11. The method as claimed in claim 10, wherein the step of laser irradiation comprises irradiating the carbon nano-tube powders with 30 kW ArKr laser.

12. The method as claimed in claim 10, wherein the carbon nano-tube powders comprise exposed carbon nano-tubes after laser irradiation.

13. The substrate structure as claimed in claim 10, wherein the carbon nano-tube powders comprise graphitized bonding in the carbon nano-tubes after laser irradiation.

14. The method as claimed in claim 8, wherein the first substrate comprises a patterned cathode structure, and wherein the paste is printed on the patterned cathode structure.

15. The method as claimed in claim 8, wherein the second substrate comprises an anode electrode and a fluorescent layer.
